(19) United States
(12) Patent Application Publication
(10) Pub. No.: US 2025/0203991 A1
(43) Pub. Date: Jun. 19, 2025

(54) INNER SPACER AND SOURCE DRAIN EPI

(71) Applicant: INTERNATIONAL BUSINESS MACHINES CORPORATION, ARMONK, NY (US)

(72) Inventors: Tao Li, Slingerlands, NY (US); Julien Frougier, Albany, NY (US); Nicolas Jean Loubet, GUILDERLAND, NY (US); Ruilong Xie, Niskayuna, NY (US)

(21) Appl. No.: 18/544,506

(22) Filed: Dec. 19, 2023

(51) Int. Cl. H01L 29/66; H01L 27/088; H01L 29/06; H01L 29/08; H01L 29/417; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 62/151; H10D 64/017; H10D 64/258; H10D 84/83

(57) ABSTRACT

A semiconductor structure including a first transistor having a first gate-to-gate space and a first source drain region, a second transistor having a second gate-to-gate space and a second source drain region, where the first gate-to-gate space is less than the second gate-to-gate space, and where a bottommost surface of the first source drain region is above a bottommost surface of the second source drain region.

### BACKGROUND

The present invention generally relates to semiconductor structures, and more particularly to nanosheet transistor structures having inner spacer and source drain epi.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a first transistor having a first gate-to-gate space and a first source drain region, a second transistor having a second gate-to-gate space and a second source drain region where the first gate-to-gate space is less than the second gate-to-gate space, and where a bottommost surface of the first source drain region is above a bottommost surface of the second source drain region.

According to another embodiment of the present invention, a semiconductor structure is provided. The semiconductor structure may include a first transistor having a first gate-to-gate space and a first source drain region, and a second transistor having a second gate-to-gate space and a second source drain region, where the gate-to-gate space is less than the gate-to-gate space, and where a bottom surface of the first source drain region is substantially flush with a bottom surface of the second source drain region, and where a bottommost surface of the second source drain region is below the bottom surface of the first source drain region.

According to another embodiment of the present invention, a semiconductor structure is provided. The semiconductor structure may include a first transistor having a gate-to-gate space and a first source drain region, where the first source drain region is composed of an epitaxial material, and a second transistor having a gate-to-gate space and a second source drain region, where the second source drain region is composed of the epitaxial material, and where the epitaxial material of the second source drain region surrounds at least two sides of a core material.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of the semiconductor structure during an intermediate step of a method of fabricating nanosheet transistor structures according to an exemplary embodiment;

FIGS. 4 and 5 are cross-sectional views of the semiconductor structure after forming and patterning a sacrificial gate dielectric (not shown) and sacrificial gates according to an exemplary embodiment;

FIGS. 6 and 7 are cross-sectional views of the semiconductor structure after removing the second sacrificial nanosheets according to an exemplary embodiment;

FIGS. 8 and 9 are cross-sectional views of the semiconductor structure after forming a spacer material according to an exemplary embodiment;

FIGS. 10 and 11 are cross-sectional views of the semiconductor structure after source drain openings and individual nanosheet stacks according to an exemplary embodiment;

FIGS. 12 and 13 are cross-sectional views of the semiconductor structure after forming a sacrificial spacer material according to an exemplary embodiment;

FIGS. 14 and 15 are cross-sectional views of the semiconductor structure after removing portions of the sacrificial spacer material according to an exemplary embodiment;

FIGS. 16 and 17 are cross-sectional views of the semiconductor structure after removing portions of the spacer material according to an exemplary embodiment;

FIGS. 18 and 19 are cross-sectional views of the semiconductor structure after forming first epitaxy according to an exemplary embodiment;

FIGS. 20 and 21 are cross-sectional views of the semiconductor structure after removing the sacrificial spacer material and forming inner spacers according to an exemplary embodiment;

FIGS. 22 and 23 are cross-sectional views of the semiconductor structure after forming second epitaxy and a dielectric layer according to an exemplary embodiment;

FIGS. 24 and 25 are cross-sectional views of the semiconductor structure after forming replacement gate structures, self-aligned gate caps, source drain contacts and back-end-of-line according to an exemplary embodiment; and

FIGS. 26 and 27 are cross-sectional views of the semiconductor structure during an intermediate step of a method of fabricating nanosheet transistor structures according to an alternative exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, forming source/drain epitaxy layer with self-aligned silicon isolation layer (SASI) presents unique challenges. More specifically, for example, conventional inner spacer fabrication and merged epitaxial source drain techniques are not reliable for designs with different gate-to-gate spacing. For example, with the presence of the self-aligned silicon isolation layer (SASI), source/drain epitaxy can only grow from sidewall of exposed nanosheet channels, and it is easy to form source/drain epi merge at relatively small gate-to-gate spacing with smaller source/drain openings, however, for devices with larger source/drain openings (especially for long channel devices with relatively large gate-to-gate spacing), source/drain epi merge becomes a problem.

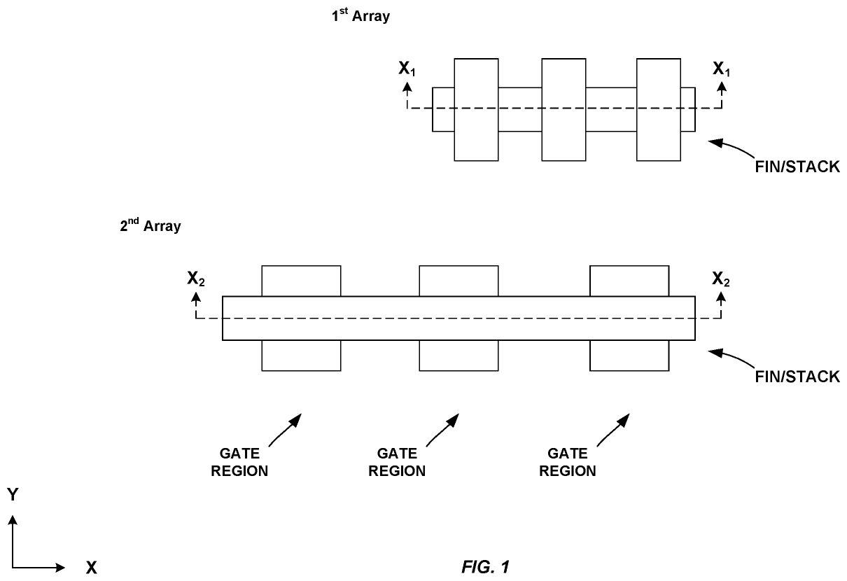

The present invention generally relates to semiconductor structures, and more particularly to nanosheet transistor structures having inner spacer and source drain epi. More specifically, the nanosheet transistor structures and associated method disclosed herein enable a novel solution for providing merged source drain epi for designs and structures with different gate-to-gate spacing. Exemplary embodiments of nanosheet transistor structures having different gate-to-gate spacing with merged source drain epi are described in detail below by referring to the accompanying drawings in FIGS. 1 to 27. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first transistor array and a second transistor array including fins/stacks and corresponding gate regions situated perpendicular to the fins/stacks. FIGS. 1-27 represent cross section views oriented as indicated in FIG. 1

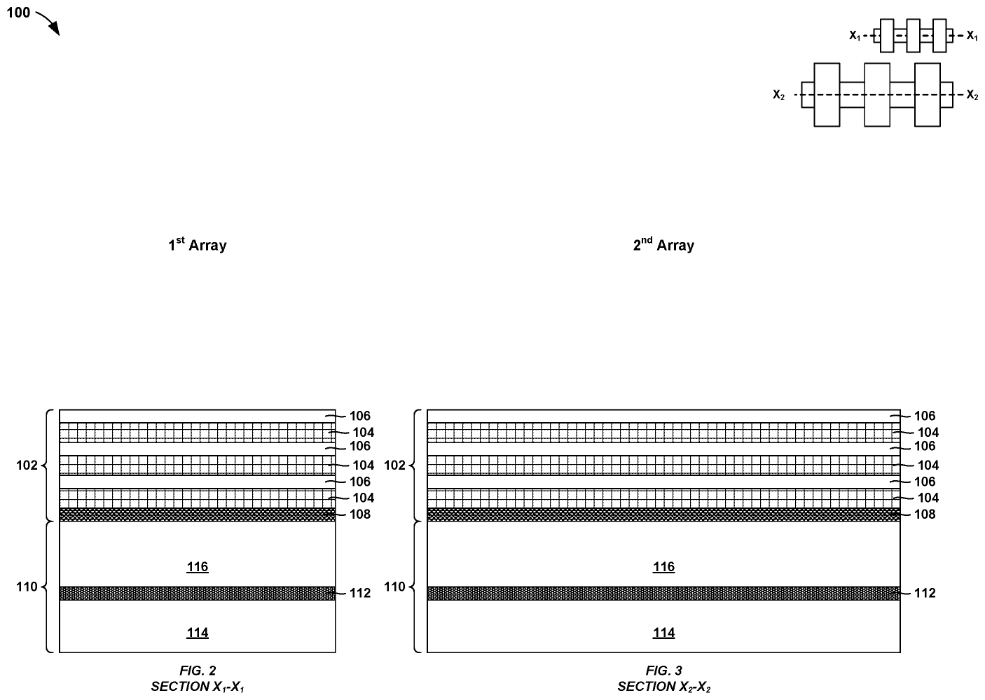

Referring now to FIGS. 2 and 3, a structure 100 is shown during an intermediate step of a method of fabricating a nanosheet transistor structure according to an embodiment of the invention. FIG. 2 depicts a cross-sectional view of the structure 100 taken along line X₁-X₁, and FIG. 3 depicts a cross-sectional view of the structure 100 taken along line X₂-X₂.

The structure 100 illustrated in FIGS. 2-3 includes nanosheet fins 102 formed from an alternating series of first silicon germanium (SiGe) sacrificial nanosheets 104 (hereinafter “first sacrificial nanosheets 104”), silicon (Si) channel nanosheets 106 (hereinafter “channel nanosheets 106”), and second silicon germanium (SiGe) sacrificial nanosheets 108 (hereinafter “second sacrificial nanosheets 108”), as illustrated. The nanosheet fins 102 are formed on a silicon substrate 110. Although only a limited number of nanosheet fins 102 and nanosheet layers are shown, one or more additional nanosheet stacks and/or nanosheets can optionally be epitaxially grown in an alternating fashion, and the properties of any additional nanosheets are the same as the corresponding nanosheets described herein.

According to embodiments of the present disclosure, the first sacrificial nanosheets 104 have a different germanium concentration than the second sacrificial nanosheets 108. In at least one embodiment, the second sacrificial nanosheets 108 have a higher germanium concentration than the first sacrificial nanosheets 104. More specifically, for example, the second sacrificial nanosheets 108 may have a germanium concentration ranging from about 45 to about 70 percent, while the first sacrificial nanosheets 104 may have a germanium concentration ranging from about 15 to about 40 percent. In all cases, the different germanium concentrations are designed to allow for each of the first sacrificial nanosheets 104 and the second sacrificial nanosheets 108 to be etched selective to one another. As such, other germanium concentrations are explicitly contemplated.

In one or more embodiments, the nanosheet fins 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, each nanosheet fin 102 includes channel nanosheets 106 which are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 110 may be a bulk substrate or a layered semiconductor substrate such as a silicon-on-insulator or SiGe-on-insulator, where an etch stop layer 112, separates a base substrate 114 from a top semiconductor layer 116. Unlike conventional layered semiconductor substrates, the etch stop layer 112 of the substrate 110 may include any material which affects the desired etch selectivity during subsequent backside processing. For example, the etch stop layer 112 may be a conventional buried oxide layer, or it may be a silicon germanium layer with a specific germanium concentration. In practice, the etch stop layer 112 will function as an etch stop layer and can be composed of any material which supports that function.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, both the etch stop layer 112 and the base substrate 114 are sacrificial and will not remain in the final structure.

Known processing techniques have been applied to the alternating layers to form the nanosheet fins 102 shown. For example, the known processing techniques can include the formation of hard masks (not shown) over the topmost layer of the nanosheet fins 102. The hard masks can be formed by first depositing the hard mask material (for example silicon nitride) onto the topmost layer of the nanosheet fins 102 using, for example, chemical vapor deposition (CVD), plasma enhanced CVD (PECVD) or any suitable technique for dielectric deposition that does not induce a physical or chemical change to the topmost layer of the nanosheet fins 102. According to an exemplary embodiment, the hard mask material is deposited onto the channel nanosheets 106 at the top of the nanosheet fins 102 and then patterned into a plurality of the individual hard masks. Patterning the hard mask is commensurate with a desired footprint and location of the nanosheet fins 102, as shown in FIG. 1. As such, FIG. 2 illustrates a cross-section view of at least a portion of a nanosheet fin in the first transistor array, and FIG. 3 illustrates a cross-section view of at least a portion of a nanosheet fin in the second transistor array.

Next, shallow trench isolation regions (not shown) are formed according to known techniques. The shallow trench isolation regions are formed at the bottom of trenches in the substrate 110 formed during patterning of the nanosheet fins 102. Specifically, a dielectric material is deposited at the bottom of trenches in the substrate 110 to isolate adjacent devices from one another according to known techniques. The shallow trench isolation regions may be formed from any appropriate dielectric material including, for example, silicon oxide (SiOₓ) or silicon nitride (SiₓN_{y}).

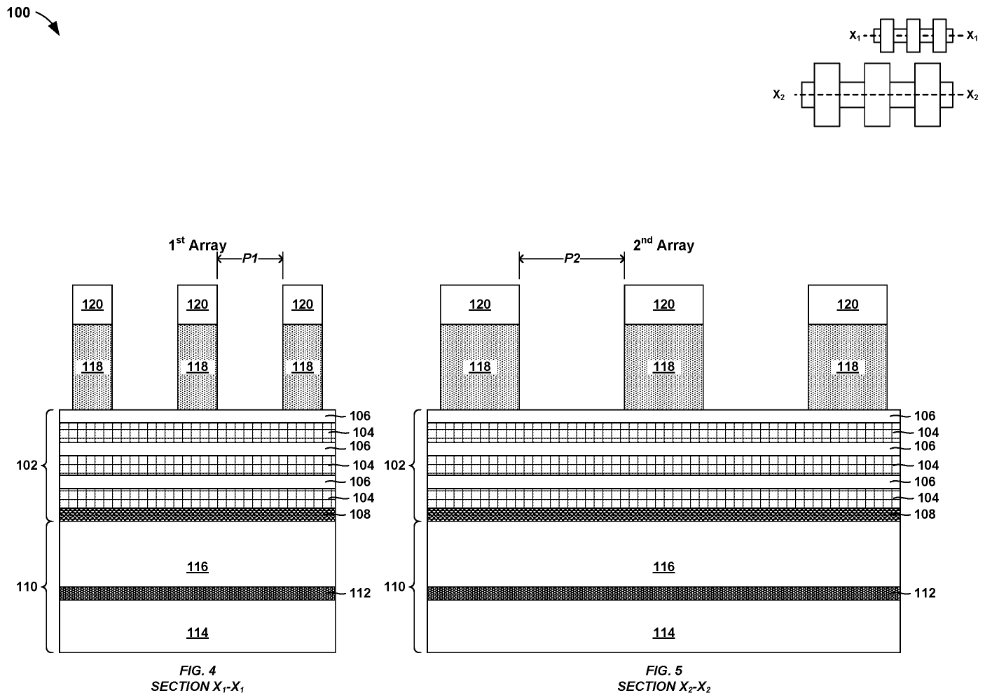

Referring now to FIGS. 4 and 5, the structure 100 is shown after forming and patterning a sacrificial gate dielectric (not shown) and sacrificial gates 118 according to an embodiment of the invention. FIG. 4 depicts a cross-sectional view of the structure 100 taken along line X₁-X₁, and FIG. 5 depicts a cross-sectional view of the structure 100 taken along line X₂-X₂.

The sacrificial gate dielectric is deposited directly on exposed surfaces of the structure 100 according to known techniques. Specifically, for example, a relatively thin layer of silicon oxide (SiO2) is first conformally deposited over and around the nanosheet fins 102, as illustrated.

A sacrificial gate material is first blanket deposited over and around the nanosheet fins 102 according to known techniques. Specifically, for example, a relatively thick layer of amorphous silicon is blanket deposited directly on the sacrificial gate dielectric, as illustrated. In this manner, both the sacrificial gate dielectric and the sacrificial gate material completely covers the nanosheet fins 102.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a gate hard mask 120 is formed over the structure 100. The gate hard mask 120 defines gate regions of individual devices. According to an exemplary embodiment, a mask material is deposited onto the sacrificial gate material and then patterned into a plurality of individual gate hard masks 120. Next, the pattern created by the individual gate hard masks 120 is transferred into the sacrificial gate dielectric and the sacrificial gate material. Specifically, portions of sacrificial gate dielectric and the sacrificial gate material are anisotropically etched or removed selective to the gate hard mask 120 to form the sacrificial gates 118, as illustrated. According to an embodiment, a silicon RIE process is used to selectively remove the portions of the sacrificial gate dielectric and the sacrificial gate material.

According to embodiments of the present invention, a first gate-to-gate space (P1) of the first transistor array is different from a second gate-to-gate space (P2) of the second transistor array. As depicted in the figured, the first gate-to-gate space (P1) is less than the second gate-to-gate space (P2). Therefore, according to embodiments disclosed herein a channel length of devices in the first transistor array will be less than a channel length of devices in the second transistor array. Said differently, devices in the first transistor array can be referred to as short-channel devices and devices in the second transistor array can be referred to as long-channel deices.

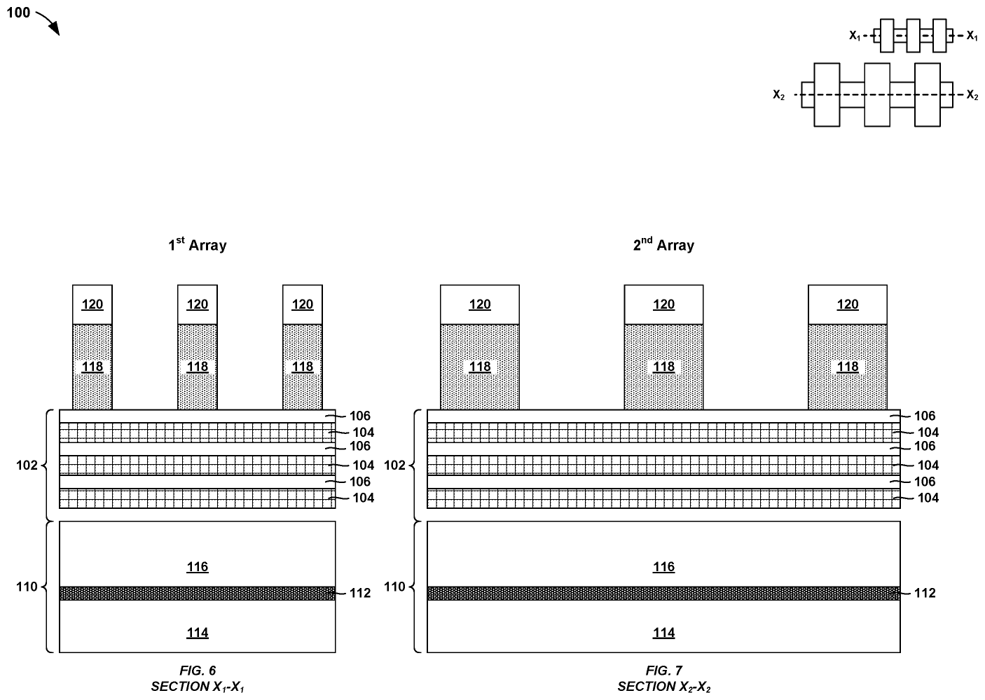

Referring now to FIGS. 6 and 7, the structure 100 is shown after removing the second sacrificial nanosheets 108 according to an embodiment of the invention. FIG. 6 depicts a cross-sectional view of the structure 100 taken along line X₁-X₁, and FIG. 7 depicts a cross-sectional view of the structure 100 taken along line X₂-X₂.

The second sacrificial nanosheets 108 are selectively removed according to known techniques. Specifically, the second sacrificial nanosheets 108 are isotropically etched and removed selective to the first sacrificial nanosheets 104 and the channel nanosheets 106 according to known techniques. According to an embodiment, a selective etching process, such as vapor phase HCl dry etch, is used to selectively remove the second sacrificial nanosheets 108. The desired etch selectivity is made possible by the different concentrations of germanium. In this case, the layers with the relatively higher germanium concentration, for example the second sacrificial nanosheets 108, are removed selective to layers with the relatively lower germanium concentrations, for example the first sacrificial nanosheets 104 and the channel nanosheets 106.

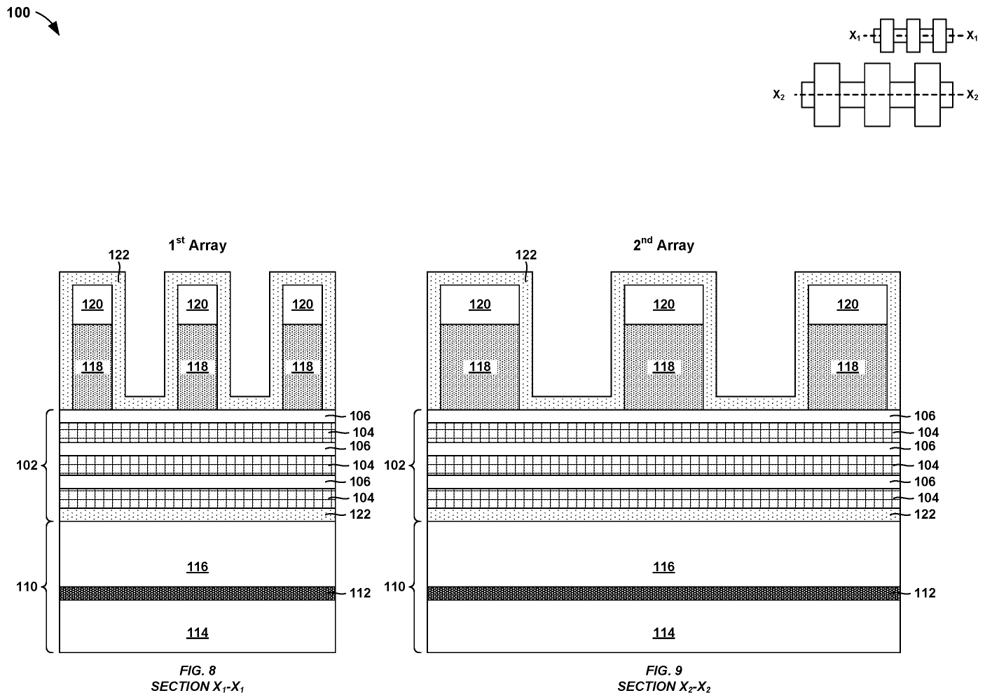

Referring now to FIGS. 8 and 9 the structure 100 is shown after forming a spacer material 122 according to an embodiment of the invention. FIG. 8 depicts a cross-sectional view of the structure 100 taken along line X₁-X₁, and FIG. 9 depicts a cross-sectional view of the structure 100 taken along line X₂-X₂.

The spacer material 122 is blanket deposited on exposed surfaces of the structure 100 according to known techniques. Specifically, for example, a relatively thin layer of silicon nitride is conformally deposited as illustrated. In some embodiments, for example, the spacer material 122 may be composed of SiN, SiBCN, SiOCN, SiOC, or any other combination of low-k materials. The term “low-k” as used throughout the present application denotes a dielectric material that has a dielectric constant of less than 4.0. According to embodiments of the present disclosure, the spacer material 122 substantially fills the space created by removing the second sacrificial nanosheets 108, and functions to isolate the nanosheet fins 102 from the substrate 110. the spacer material 122 is commonly referred to in as a self-aligned silicon isolation (SASI) layer).

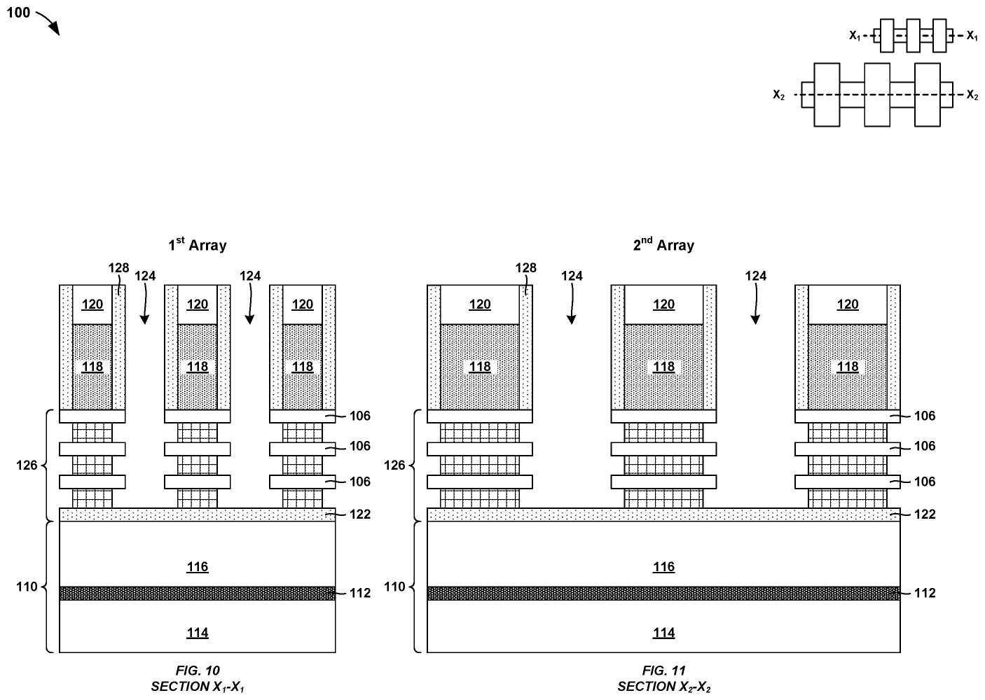

Referring now to FIGS. 10 and 11, the structure 100 is shown after forming source drain openings 124 and individual nanosheet stacks 126 according to an embodiment of the invention. FIG. 10 depicts a cross-sectional view of the structure 100 taken along line X₁-X₁, and FIG. 11 depicts a cross-sectional view of the structure 100 taken along line X₂-X₂.

First, in at least an embodiment, portions of the spacer material 122 are selectively removed or etched from horizontal surfaces according to known techniques. Doing so will generally expose topmost surfaces of the individual gate hard masks 120 and the nanosheet fins 102. Portions of the spacer material 122 remaining on sidewalls of the sacrificial gates 118 are hereinafter referred to as gate spacers 128.

Next, portions of the nanosheet fins 102 are etched and removed from between the sacrificial gates 118 according to known techniques. Specifically, the pattern created by the individual gate hard masks 120 and the gate spacers 128 is transferred into the nanosheet fins 102 to create the individual nanosheet stacks 126, as illustrated. In doing so, portions of the first sacrificial nanosheets 104 and the channel nanosheets 106, are removed selective to the spacer material 122, as illustrated.

In an embodiment, portions of the nanosheet fins 102 are removed using an anisotropic etch such as, for example, reactive ion etching. Doing so may require a series of multiple etching steps using different etch chemistries as is well known in the art. Etching is designed to expose ends of individual nanosheet layers and define the source drain openings 124. In all cases, etching stops before exposing the substrate 110. Said differently, portions of the spacer material 122 at bottoms of the source drain openings 124 may remain, as illustrated.

Finally, after patterning the nanosheet fins 102 and creating the individual nanosheet stacks 126, the first sacrificial nanosheets 104 are laterally recessed to make room for the inner spacers according to known techniques. In one or more embodiments, the first sacrificial nanosheets 104 are laterally recessed using a hydrogen chloride (HCL) gas isotropic etch process, which etches silicon germanium without attacking silicon. In other embodiments, the first sacrificial nanosheets 104 are laterally recessed using a ClF3 etch process. As illustrated, cavities are formed by spaces that were occupied by the removed portions of the first sacrificial nanosheets 104.

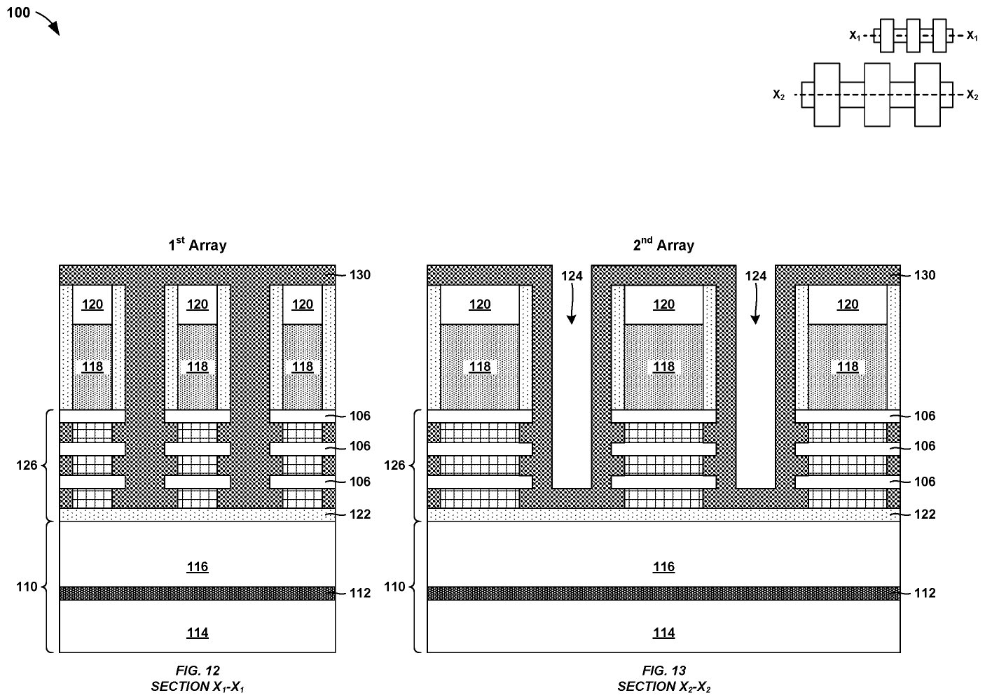

Referring now to FIGS. 12 and 13, the structure 100 is shown after forming a sacrificial spacer material 130 according to an embodiment of the invention. FIG. 12 depicts a cross-sectional view of the structure 100 taken along line X₁-X₁, and FIG. 13 depicts a cross-sectional view of the structure 100 taken along line X₂-X₂.

The sacrificial spacer material 130 is blanket deposited on exposed surfaces of the structure 100 according to known techniques. Specifically, for example, a layer of SiOC is conformally deposited as illustrated. In some embodiments, for example, the sacrificial spacer material 130 may be composed of SiN, SiBCN, SiOCN, or any other combinations of low-k materials. In all cases, the sacrificial spacer material 130 should be made from a material which preferably offers effective etch selectivity during subsequent processing. For example, the sacrificial spacer material 130 should be capable of being removed selective to at least the gate spacers 128 (i.e. the spacer material 122) and other surrounding structures during subsequent processing.

According to embodiments of the present disclosure, the gate spacers 128 (i.e. the spacer material 122) and the sacrificial spacer material 130 are made from different low-k materials. For example, the gate spacers 128 (i.e. the spacer material 122) are made from SiN, and the sacrificial spacer material 130 is made of SiOC.

In all cases, the sacrificial spacer material 130 is deposited with a thickness sufficient to reduce the lateral width of the source drain openings 124 in the second transistor array without pinching-off or otherwise filling them entirely. In doing so, the source drain openings 124 in the first transistor array will likely be filled entirely as a result of the first gate-to-gate space (P1) of the first transistor array being smaller than the second gate-to-gate space (P2) of the second transistor array (See FIGS. 4 and 5).

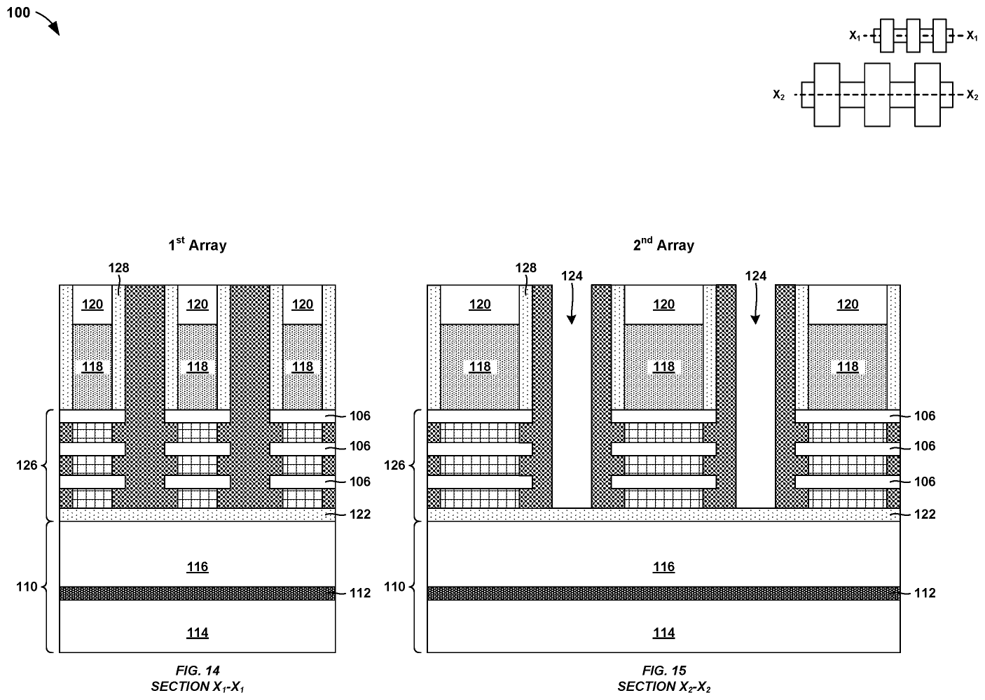

Referring now to FIGS. 14 and 15, the structure 100 is shown after removing portions of the sacrificial spacer material 130 according to an embodiment of the invention. FIG. 14 depicts a cross-sectional view of the structure 100 taken along line X₁-X₁, and FIG. 15 depicts a cross-sectional view of the structure 100 taken along line X₂-X₂.

Portions of the sacrificial spacer material 130 are removed from horizontal surfaces according to known techniques. Specifically, portions of the sacrificial spacer material 130 on topmost surfaces of the structure 100 and at bottoms of the source drain openings 124 are etched and removed using an anisotropic etching technique. In doing so, portions of the spacer material 122 will become exposed at the bottoms of the source drain openings 124 in the second transistor array. After etching, portions of the sacrificial spacer material 130 remain along sidewalls of the source drain openings 124 and within the cavities formed by laterally recessing the first sacrificial nanosheets 104, in the second transistor array. Although portions of the sacrificial spacer material 130 are removed from horizontal surfaces across the entire structure 100, including both the first transistor array and the second transistor array, the source drain openings 124 in the first transistor array remain substantially filled with the sacrificial spacer material 130.

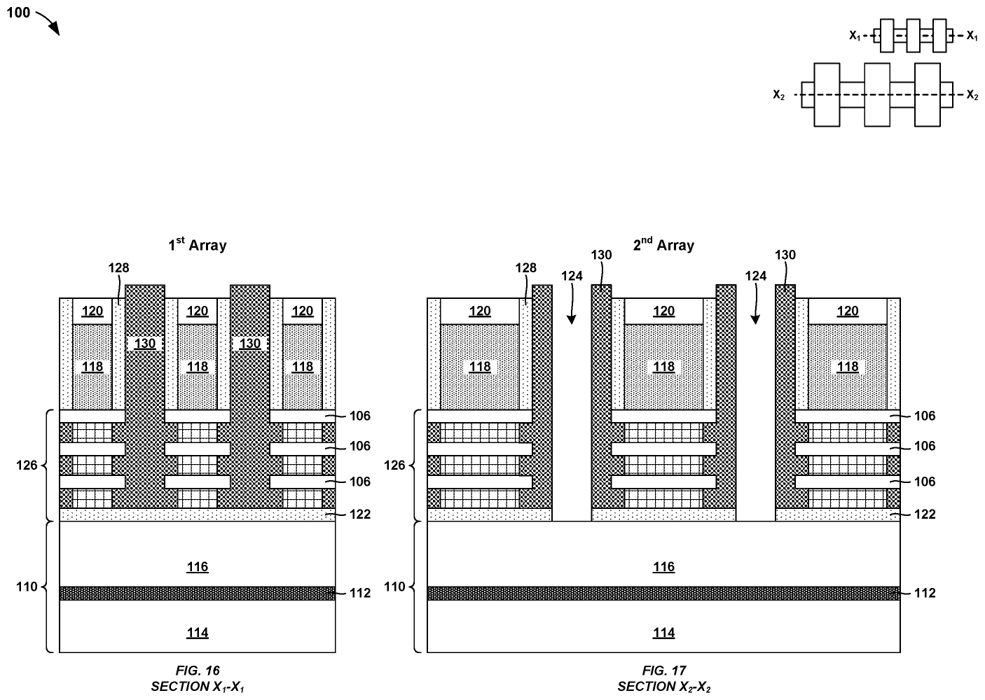

Referring now to FIGS. 16 and 17, the structure 100 is shown after removing portions of the spacer material 122 according to an embodiment of the invention. FIG. 16 depicts a cross-sectional view of the structure 100 taken along line X₁-X₁, and FIG. 17 depicts a cross-sectional view of the structure 100 taken along line X₂-X₂.

Portions of the spacer material 122 exposed at bottoms of the source drain openings 124 in the second transistor array are removed according to known techniques. Specifically, the exposed portions of the spacer material 122 are etched and removed selective to the sacrificial spacer material 130 using an anisotropic etching technique such as RIE. After etching, the substrate 110 will be exposed at the bottoms of the source drain openings 124 in the second transistor array, as illustrated. In doing so, the individual gate hard masks 120 and the gate spacers 128 may also be recessed selective to the sacrificial spacer material 130 depending on the selectivity of the chosen etching technique.

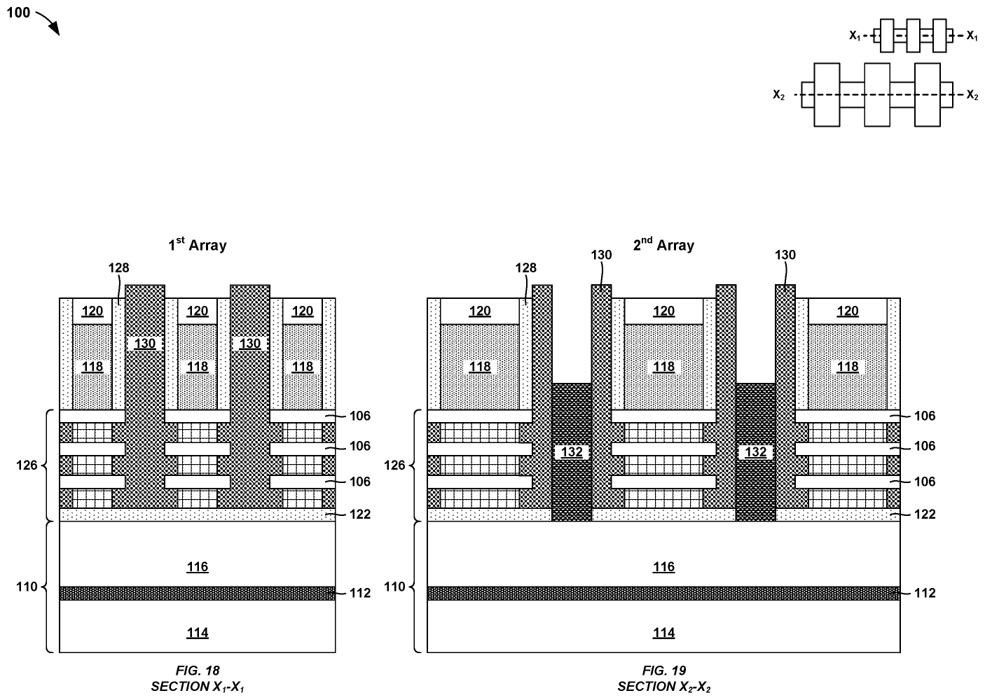

Referring now to FIGS. 18 and 19, the structure 100 is shown after forming first epitaxy 132 according to an embodiment of the invention. FIG. 18 depicts a cross-sectional view of the structure 100 taken along line X₁-X₁, and FIG. 19 depicts a cross-sectional view of the structure 100 taken along line X₂-X₂.

The first epitaxy 132 are formed using an epitaxial layer growth process from the exposed surface of the substrate 110 according to known techniques. Typically, in-situ doping is used to dope the first epitaxy 132, creating the desired doping level for subsequently formed source drain regions. The first epitaxy 132 should be grown to a height approximately equal to or greater than the heights of the individual nanosheet stacks 126, as illustrated. Doing so will ensure sufficient material remains after the subsequent removal of the sacrificial spacer material 130. If the first epitaxy 132 is grown to a height too low there is a possibility that air gaps or voids may form in the source drain regions and thereby lead to performance degradation. Lastly, it is noted that the first epitaxy 132 does not form in the first transistor array due to the presence of the sacrificial spacer material 130, as illustrated. Some erosion or recessing of the first epitaxy 132 is anticipated. The formation of the first epitaxy 132 in the second transistor array, that is the transistor arrays having larger gate-to-gate space, subsequent source/drain epi merge is now possible. Without the first epitaxy 132, source/drain epi merge in transistor arrays having larger gate-to-gate space is otherwise very difficult or unsuccessful.

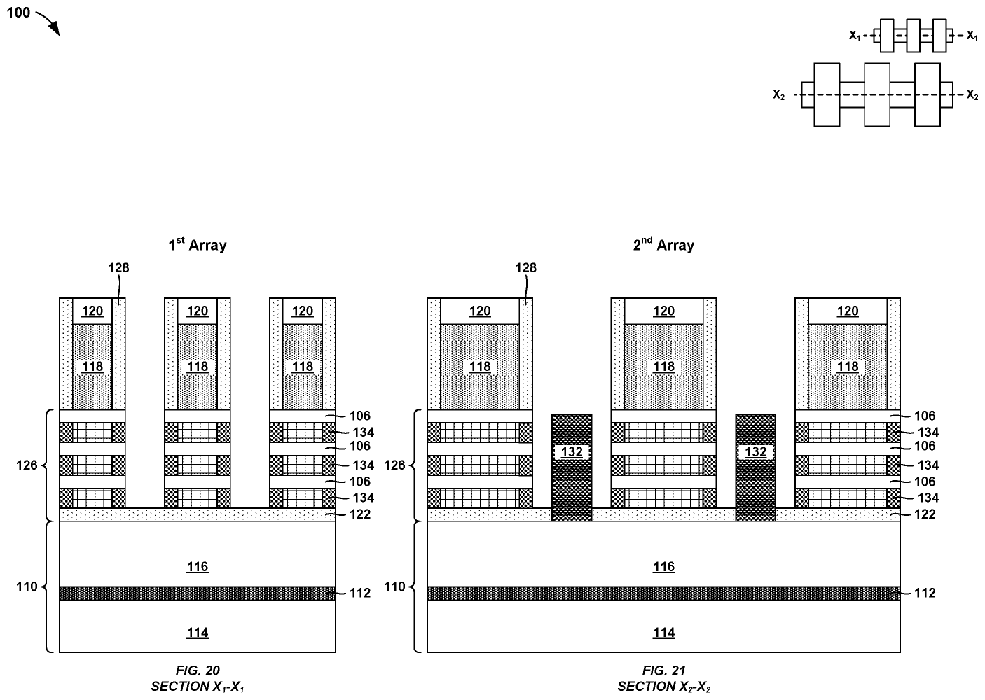

Referring now to FIGS. 20 and 21, the structure 100 is shown after removing the sacrificial spacer material 130 and forming inner spacers 134 according to an embodiment of the invention. FIG. 20 depicts a cross-sectional view of the structure 100 taken along line X₁-X₁, and FIG. 21 depicts a cross-sectional view of the structure 100 taken along line X₂-X₂.

First, the sacrificial spacer material 130 is removed according to known techniques. Specifically, the sacrificial spacer material 130 is etched and selectively removed from the entire structure 100 using an anisotropic etching technique, such as, for example, reactive ion etching. In all cases, the first epitaxy 132 and the channel nanosheets 106 should be completely exposed after removing the sacrificial spacer material 130. If not, subsequent epitaxial growth techniques may result in defects and negatively affect device performance. Furthermore, directional etching of the sacrificial spacer material 130 should be performed in a manner such that portions remain in the cavities formed by spaces that were occupied by the removed portions of the first sacrificial nanosheets 104. The remaining portions of the sacrificial spacer material 130 are conventionally known and referred to as inner spacers 134.

The inner spacers 134 are positioned such that subsequent etching processes used to remove the first sacrificial nanosheets 104 during subsequent replacement gate processing do not also attack subsequently formed source drain regions.

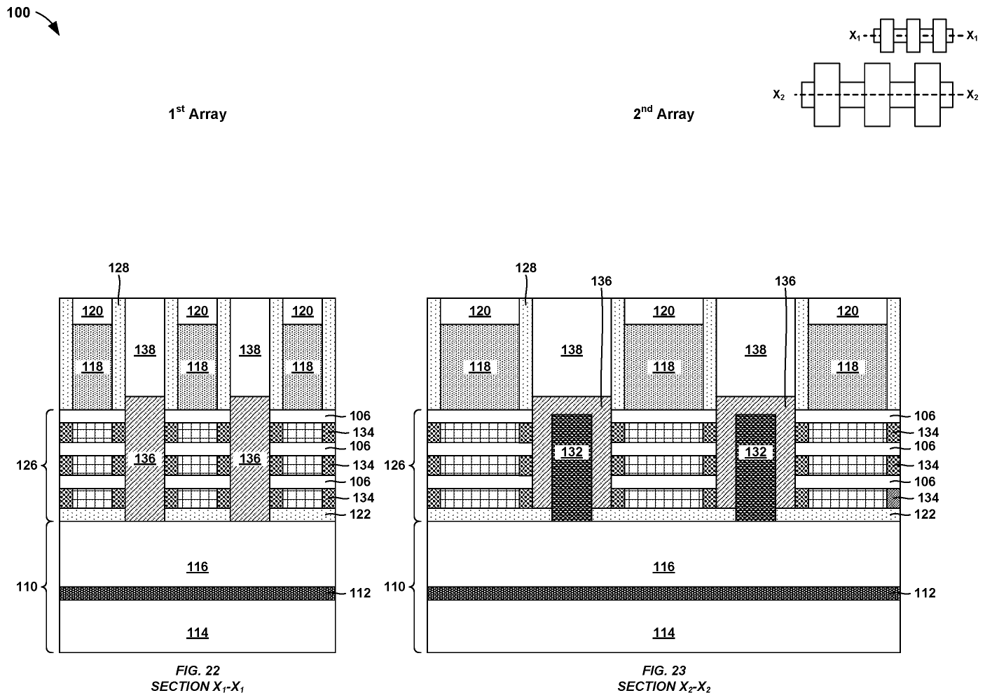

Referring now to FIGS. 22 and 23, the structure 100 is shown after forming second epitaxy 136 and a dielectric layer 138 according to an embodiment of the invention. FIG. 22 depicts a cross-sectional view of the structure 100 taken along line X₁-X₁, and FIG. 23 depicts a cross-sectional view of the structure 100 taken along line X₂-X₂.

The second epitaxy 136 are formed using an epitaxial layer growth process on the exposed ends of the channel nanosheets 106 according to known techniques. Typically, in-situ doping is used to dope the second epitaxy 136, thereby creating the necessary junctions of the semiconductor device. The second epitaxy 136 should be grown to a height, or thickness, sufficient to fill the space between the ends of the channel nanosheets 106 and the first epitaxy 132, as illustrated.

Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the disclosure, the second epitaxy 136 alone will become the source drain regions for the short channel devices of the first transistor array; however, both the first epitaxy 132 and the second epitaxy 136 together will become the source drain region for the long channel devices of the second transistor array. As such, each of the first epitaxy 132 and the second epitaxy 136 can be doped accordingly to achieve the desired function.

According to embodiments of the disclosure, at least some of the source drain regions are of a first-type, for example, P-type, and at least some of the source drain regions are of a second-type, for example, N-type. In yet another example, the source drain regions for the short channel devices (i.e. 136) of the first transistor array are a first type, and the source drain regions for the long channel devices (132 and 136) of the second transistor array are a second type. According to yet another embodiment, both the first epitaxy 132 and the second epitaxy 136 are doped with similar dopants. Alternatively, in other embodiments, the first epitaxy 132 and the second epitaxy 136 are doped with different dopants.

The dielectric layer 138 is formed by blanket depositing an interlayer dielectric material over the structure 100 according to known techniques. Specifically, the dielectric layer 138 is formed on the second epitaxy 136 and substantially fills the remaining space between the gate spacers 128, as illustrated.

The dielectric layer 138 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 138. Using a self-planarizing dielectric material as the dielectric layer 138 can avoid the need to perform a subsequent planarizing step.

After the dielectric layer 138 is formed, the structure is polished according to known techniques, such as, for example, chemical mechanical polishing techniques. Specifically, the dielectric layer 138, the gate spacers 128, and the gate hard mask 120 are polished until a topmost surface of the dielectric layer 138 is flush, or substantially flush, with topmost surfaces of the gate spacers 128 and the gate hard mask 120.

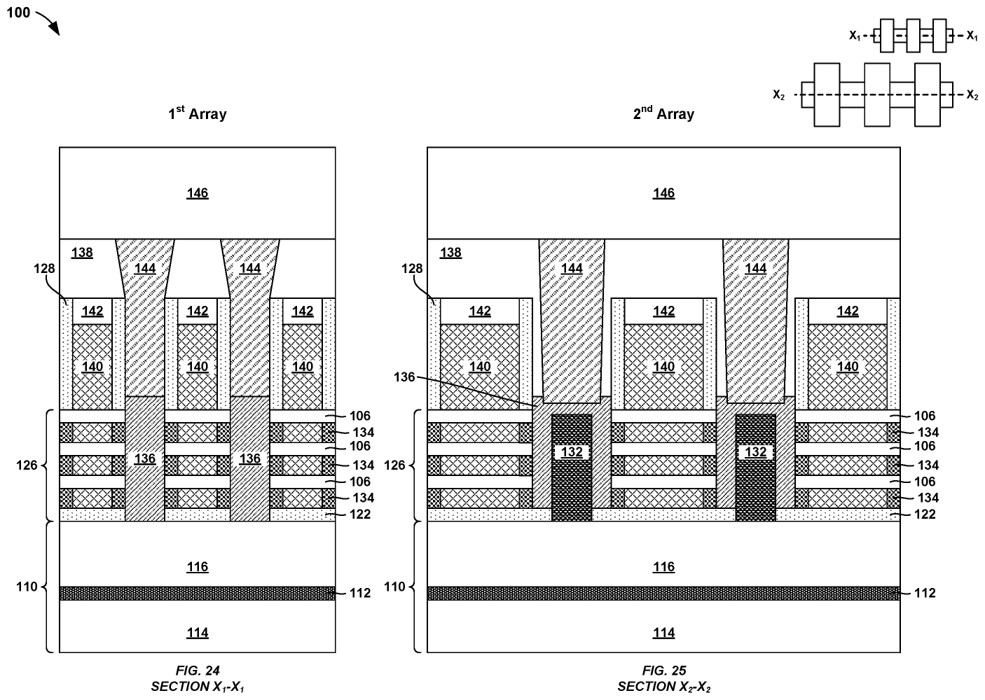

Referring now to FIGS. 24 and 25, the structure 100 is shown after forming replacement gate structures 140, self-aligned gate caps 142, source drain contacts 144 and back-end-of-line 146 according to an embodiment of the invention. FIG. 24 depicts a cross-sectional view of the structure 100 taken along line X₁-X₁, and FIG. 25 depicts a cross-sectional view of the structure 100 taken along line X₂-X₂.

First, the individual gate hard masks 120 and the sacrificial gates 118 are removed according to known techniques. Specifically, the individual gate hard masks 120 and the sacrificial gates 118 are removed selective to the gate spacers 128, the channel nanosheets 106, and the inner spacers 134 according to known techniques.

Next, the sacrificial nanosheets 104 are removed according to known techniques. Specifically, the sacrificial nanosheets 104 are removed selective to the channel nanosheets 106, the inner spacers 134, and the spacer material 122 according to known techniques. Doing so is made possible by the different concentrations of germanium, as previously discussed above.

Next, the replacement gate structures 140 are formed according to known techniques. Specifically, the replacement gate structures 140 are formed within the spaces previously occupied by the sacrificial gates 118 and the sacrificial nanosheets 104. According to an embodiment, the replacement gate structures 140 may include a gate dielectric, a work function metal layer, and a gate metal.

Next, the self-aligned gate caps 142 are formed according to known techniques. Specifically, the self-aligned gate caps 142 are formed by first recessing the replacement gate structures 140 and subsequently depositing a suitable capping material according to known techniques. It is noted, both the replacement gate structures 140 and the self-aligned gate caps 142 remain flanked by the gate spacers 128 as illustrated. Further, known polishing techniques may be applied to remove excess capping materials. In doing so, topmost surfaces of the gate spacers 128 will be flush, or substantially flush, with topmost surfaces of the self-aligned gate caps 142, as illustrated.

After forming the self-aligned gate caps 142, additional interlayer dielectric material is deposited according to known techniques. The dielectric layer 138 illustrated in the figures includes the additional interlayer dielectric material.

Next, portions of the dielectric layer 138 are removed to expose the second epitaxy 136. Next, the openings, or contact trenches, are filled with a conductive material to form the source drain contacts 144 according to known techniques. The source drain contacts 144 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. It is noted, due to the different gate pitches of the first transistor array and the second transistor array, the source drain contacts 144 directly contact the gate spacers 128 in the first transistor array and the source drain contacts 144 do not contact the gate spacers 128 in the second transistor array, as illustrated. As such, the source drain contacts 144 in the first transistor array are self-aligned to the gate spacers 128, and thus may be referred to as self-aligned contact structures.

Finally, the back-end-of-line 146 (hereinafter BEOL 146) is formed according to an embodiment of the invention. After forming the source drain contacts 144, the BEOL 146 is subsequently formed according to known techniques.

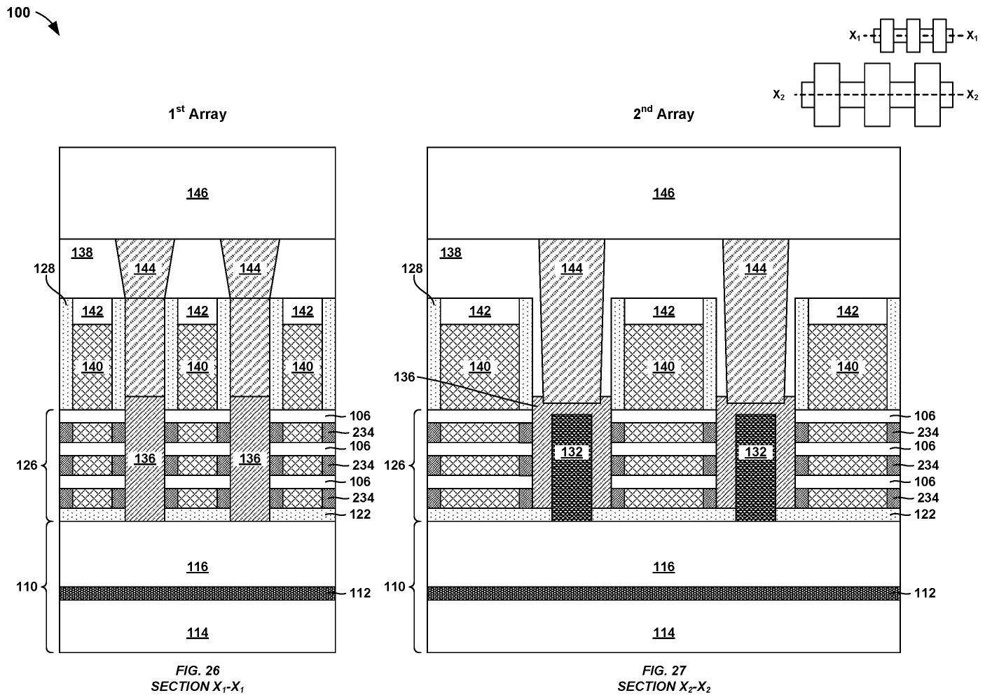

Referring not to FIGS. 26 and 27, a structure 200 is shown during an intermediate step of a method of fabricating a nanosheet transistor structure according to an alternative embodiment of the invention. An alternative embodiment is described in detail below by referring to the accompanying drawings FIGS. 26 and 27.

In the present embodiment, the inner spacers 234 of the structure 200 are not formed from the sacrificial spacer material 130, and thus have a different material composition than the sacrificial spacer material 130. In contrast, the inner spacers 134 of the structure 100 are formed from, and thus identical in composition, as the sacrificial spacer material 130. Further, the sacrificial spacer material 130 is removed in its entirety in the structure 200, but remains, in part, in the structure 100.

According to embodiments illustrated by the structure 200, the sacrificial spacer material 130 is removed in its entirety and subsequently replaced with the inner spacers 234. Despite adding an additional step, doing so enables formation of inner spacers having a different material composition from the sacrificial spacer material 130. Such may be desirable if a first material is used for the sacrificial spacer material 130 to achieve desired etch selectivity and a second material is used for the inner spacers to achieve desired electrical insulation characteristics. Said differently, a material which provides adequate etch selectivity necessary to create the first epi and the second epi may not provide the desired electrical isolation characteristics. Therefore, the structure 200 provides an alternative to enable desired fabrication and operational characteristics. In at least one example, the inner spacers 234 of the structure 200 may be made from the same material as the gate spacer 128 which is otherwise not possible in the structure 100.

With continued reference to FIGS. 24-27, and according to an embodiment, the structure 100 includes a first transistor having a first gate-to-gate space and a first source drain region, and a second transistor having a second gate-to-gate space and a second source drain region, where the first gate-to-gate space is less than the second gate-to-gate space, and where a bottommost surface of the first source drain region is above a bottommost surface of the second source drain region.

With continued reference to FIG. 24-27, and according to an embodiment, the structure further includes a first spacer separating a first gate region of the first transistor from an underlying substrate, where the first source drain region is in direct contact with only sidewalls of the first source drain region, and a second spacer separating a second gate region of the second transistor from the underlying substrate, where the second source drain region is in direct contact with a top and a side the second source drain region.

With continued reference to FIG. 24-27, and according to an embodiment, the structure further includes a first source drain contact above and directly contacting the first source drain region, and a second source drain contact above and directly contacting the second source drain region, where the first source drain contact is self-aligned to first gate spacers, and the second source drain contact is separated from second gate spacers by an interlevel dielectric.

With continued reference to FIG. 24-27, and according to an embodiment, the first source drain region and the second source drain region are composed of the same epitaxial material.

With continued reference to FIG. 24-27, and according to an embodiment, the second source drain region is composed of at least two different epitaxial materials.

With continued reference to FIG. 24-27, and according to an embodiment, the second source drain region is laterally wider than the first source drain region.

With continued reference to FIG. 24-27, and according to an embodiment, the first transistor and the second transistor are nanosheet transistors.

With continued reference to FIG. 24-27, and according to an embodiment, the structure 100 includes a first transistor having a first gate-to-gate space and a first source drain region, a second transistor having a second gate-to-gate space and a second source drain region, where the gate-to-gate space is less than the gate-to-gate space, and where a bottom surface of the first source drain region is substantially flush with a bottom surface of the second source drain region, and where a bottommost surface of the second source drain region is below the bottom surface of the first source drain region.

With continued reference to FIG. 24-27, and according to an embodiment, the structure 100 includes a first transistor having a gate-to-gate space and a first source drain region, where the first source drain region is composed of an epitaxial material, and a second transistor having a gate-to-gate space and a second source drain region, where the second source drain region is composed of the epitaxial material, and where the epitaxial material of the second source drain region surrounds at least two sides of a core material

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first transistor comprising a first gate-to-gate space and a first source drain region; and
a second transistor comprising a second gate-to-gate space and a second source drain region,
wherein the first gate-to-gate space is less than the second gate-to-gate space, and wherein a bottommost surface of the first source drain region is above a bottommost surface of the second source drain region.

2. The semiconductor structure according to claim 1, further comprising:
a first spacer separating a first gate region of the first transistor from an underlying substrate, wherein the first source drain region is in direct contact with only sidewalls of the first spacer; and
a second spacer separating a second gate region of the second transistor from the underlying substrate, wherein the second source drain region is in direct contact with a top and a side of the second spacer.

3. The semiconductor structure according to claim 1, further comprising:
a first source drain contact above and directly contacting the first source drain region; and
a second source drain contact above and directly contacting the second source drain region,
wherein the first source drain contact is self-aligned to first gate spacers, and the second source drain contact is separated from second gate spacers by an interlevel dielectric.

4. The semiconductor structure according to claim 1, wherein the first source drain region and the second source drain region are composed of the same epitaxial material.

5. The semiconductor structure according to claim 1, wherein the second source drain region is composed of at least two different epitaxial materials.

6. The semiconductor structure according to claim 1, wherein the second source drain region is laterally wider than the first source drain region.

7. The semiconductor structure according to claim 1, wherein the first transistor and the second transistor are nanosheet transistors.

8. A semiconductor structure comprising:
a first transistor comprising a first gate-to-gate space and a first source drain region; and
a second transistor comprising a second gate-to-gate space and a second source drain region,
wherein the first gate-to-gate space is less than the second gate-to-gate space, and wherein a bottom surface of the first source drain region is substantially flush with a bottom surface of the second source drain region, and wherein a bottommost surface of the second source drain region is below the bottom surface of the first source drain region.

9. The semiconductor structure according to claim 1, further comprising:
a first spacer separating a first gate region of the first transistor from an underlying substrate, wherein the first source drain region is in direct contact with only sidewalls of the first spacer; and
a second spacer separating a second gate region of the second transistor from the underlying substrate, wherein the second source drain region is in direct contact with a top and a side the second spacer.

10. The semiconductor structure according to claim 1, further comprising:
a first source drain contact above and directly contacting the first source drain region;
a second source drain contact above and directly contacting the second source drain region,
wherein the first source drain contact is self-aligned to first gate spacers, and the second source drain contact is separated from second gate spacers by an interlevel dielectric.

11. The semiconductor structure according to claim 1, wherein the first source drain region and the second source drain region are composed of the same epitaxial material.

12. The semiconductor structure according to claim 1, wherein the second source drain region is composed of at least two different epitaxial materials.

13. The semiconductor structure according to claim 1, wherein the second source drain region is laterally wider than the first source drain region.

14. The semiconductor structure according to claim 1, wherein the first transistor and the second transistor are nanosheet transistors.

15. A semiconductor structure comprising:
a first transistor comprising a first gate-to-gate space and a first source drain region, wherein the first source drain region is composed of an epitaxial material; and
a second transistor comprising a second gate-to-gate space and a second source drain region, wherein the second source drain region is composed of the epitaxial material, and wherein the epitaxial material of the second source drain region surrounds at least two sides of a core material.

16. The semiconductor structure according to claim 1, further comprising:
a first spacer separating a first gate region of the first transistor from an underlying substrate, wherein the first source drain region is in direct contact with only sidewalls of the first spacer; and
a second spacer separating a second gate region of the second transistor from the underlying substrate, wherein the second source drain region is in direct contact with a top and a side the spacer.

17. The semiconductor structure according to claim 1, further comprising:
a first source drain contact above and directly contacting the first source drain region;
a second source drain contact above and directly contacting the second source drain region,
wherein the first source drain contact is self-aligned to first gate spacers, and the second source drain contact is separated from second gate spacers by an interlevel dielectric.

18. The semiconductor structure according to claim 1, wherein the first source drain region and the second source drain region are composed of the same epitaxial material.

19. The semiconductor structure according to claim 1, wherein the second source drain region is composed of at least two different epitaxial materials.

20. The semiconductor structure according to claim 1, wherein the second source drain region is laterally wider than the first source drain region.
